(19) United States
(12) Patent Application Publication
(10) Pub. No.: US 2023/0230861 A1
(43) Pub. Date: Jul. 20, 2023

(54) SUBSTRATE PROCESSING APPARATUS, METHOD OF PROCESSING SUBSTRATE, METHOD OF MANUFACTURING SEMICONDUCTOR DEVICE AND RECORDING MEDIUM

(71) Applicant: Kokusai Electric Corporation, Tokyo (JP)

(72) Inventors: Takefumi MORI, Toyama-shi (JP); Yuji TAKEBAYASHI, Toyama-shi (JP); Makoto HIRANO, Toyama-shi (JP); Takatomo YAMAGUCHI, Toyama-shi (JP); Yusaku OKAJIMA, Toyama-shi (JP)

(73) Assignee: Kokusai Electric Corporation, Tokyo (JP)

(21) Appl. No.: 18/189,472

(22) Filed: Mar. 24, 2023

Related U.S. Application Data
(63) Continuation of application No. PCT/JP21/33875, filed on Sep. 15, 2021.

(30) Foreign Application Priority Data
Sep. 25, 2020 (JP) 2020-160830

(51) Int. Cl. H01L 21/67; C23C 16/44; H01L 21/677

(52) U.S. Cl. CPC H01L 21/67196; C23C 16/4412; H01L 21/6719; H01L 21/6776

(57) ABSTRACT

A substrate processing technique including: a module including a gas supplier having an upstream side gas guide and a supply structure, a reaction tube communicating with the gas supplier, and a gas exhauster; a supply pipe connected to the gas supplier, and an exhaust pipe connected to the gas exhauster; a carry chamber adjacent to a plurality of the modules; and a piping arrangement region in which the supply pipe or the exhaust pipe can be arranged, in which the reaction tube is disposed at a position overlapping the carry chamber, when the supply pipe is disposed in the piping arrangement region, the gas exhauster is disposed at a position oblique to the shaft and not overlapping the carry chamber, and when the exhaust pipe is disposed in the piping arrangement area, the gas supplier is disposed at a position oblique to the shaft and not overlapping the carry chamber.

### CROSS-REFERENCE TO RELATED APPLICATIONS

This application is a Bypass Continuation Application of PCT International Application No. PCT/JP2021/033875, filed on Sep. 15, 2021, in the WIPO, and Japanese Patent Application No. 2020-160830, filed on Sep. 25, 2020, in the Japanese Patent Office, the entire contents of which are hereby incorporated by reference.

### FIELD

The present disclosure relates to a substrate processing apparatus, a method of processing a substrate, a method of manufacturing a semiconductor device, and a recording medium.

### BACKGROUND

As one aspect of a substrate processing apparatus used in a manufacturing step of a semiconductor device, for example, a substrate processing apparatus that collectively processes a plurality of substrates is used. In such a substrate processing apparatus, it is required to reduce the footprint (occupied area at the time of installation) as much as possible due to the restriction of the area of the installation place.

### SUMMARY

The present disclosure provides a technique that can reduce a footprint.

There is provided a technique including: a module including a gas supplier having an upstream side gas guide and a supply structure, a reaction tube communicating with the gas supplier, and a gas exhauster provided at a position opposing the upstream side gas guide and having a downstream side gas guide and an exhaust structure; a supply pipe connected to the gas supplier, and an exhaust pipe connected to the gas exhauster; a carry chamber adjacent to a plurality of the modules; and a piping arrangement region on a lateral of the carry chamber and adjacent to the module, the piping arrangement region in which the supply pipe or the exhaust pipe can be arranged, in which the reaction tube is disposed at a position overlapping the carry chamber on a shaft of the substrate processing apparatus in a long direction, when the supply pipe is disposed in the piping arrangement region, the gas exhauster is disposed at a position oblique to the shaft and not overlapping the carry chamber, and when the exhaust pipe is disposed in the piping arrangement area, the gas supplier is disposed at a position oblique to the shaft and not overlapping the carry chamber.

### BRIEF DESCRIPTION OF THE DRAWINGS

FIG. 1 is an explanatory view that illustrates a schematic configuration example of a substrate processing apparatus according to one aspect of the present disclosure.

FIG. 2 is an explanatory view that illustrates a schematic configuration example of the substrate processing apparatus according to one aspect of the present disclosure.

FIG. 3 is an explanatory view that explains an external appearance example of the substrate processing apparatus according to one aspect of the present disclosure.

FIG. 4 is an explanatory view that illustrates a schematic configuration example of the substrate processing apparatus according to one aspect of the present disclosure.

FIG. 5 is an explanatory view that explains a substrate support according to one aspect of the present disclosure.

FIGS. 6A to 6C are explanatory views that explain a gas supply system according to one aspect of the present disclosure.

FIGS. 7A and 7B are explanatory views that explain a gas exhaust system according to one aspect of the present disclosure.

FIG. 8 is an explanatory view that explains a controller of the substrate processing apparatus according to one aspect of the present disclosure.

FIG. 9 is a flowchart that explains a substrate processing flow according to one aspect of the present disclosure.

### DETAILED DESCRIPTION

Hereinafter, an embodiment of the present aspect will be described with reference to the drawings. The drawings used in the following description are all schematic, and dimensional relationships of elements, ratios of the elements, and the like in the drawings do not necessarily coincide with actual ones. Dimensional relationships of elements, ratios of the elements, and the like do not necessarily coincide among the plurality of drawings.

### (1) Configuration of Substrate Processing Apparatus

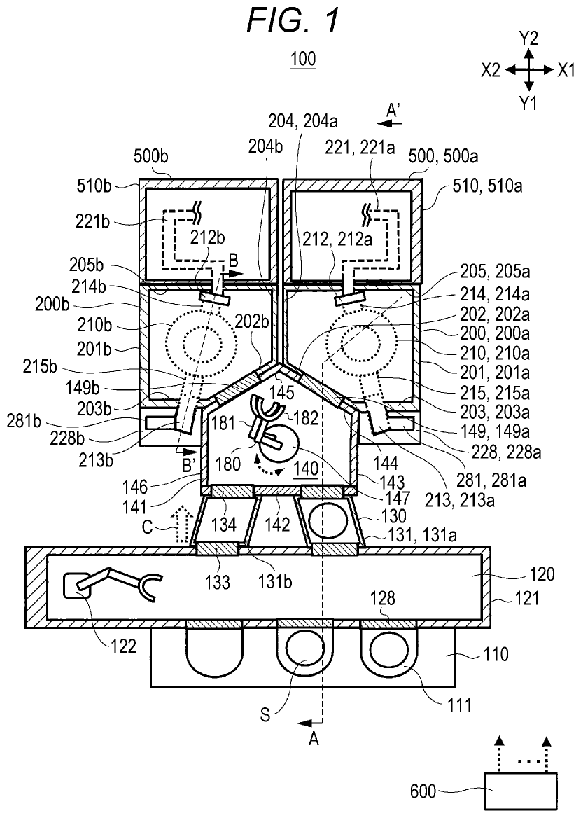

A schematic configuration of a substrate processing apparatus according to one aspect of the present disclosure will be described with reference to FIGS. 1 to 7. FIG. 1 is a transverse cross-sectional view that illustrates a configuration example of a substrate processing apparatus according to the present aspect. In FIG. 1, for convenience of description, a direction from the left side (for example, a module 200b side) to the right side (for example, a module 200a side) in the drawing is called an X axis, and a direction from the front (for example, a load port 110 side) to the back (for example, a module 200 side) is called a Y axis. In the X axis, the left side in the drawing is called X2, the right side is called X1, and in the Y axis, the front side is called Y1, and the back side is called Y2.

As described later, since the two modules 200 (200a and 200b) are configured to be adjacent to each other in the X axis direction, the X axis direction is also called a direction in which the modules 200 are arrayed.

The direction from Y1 to Y2 may be expressed as follows. As described later, since a substrate S moves between an IO stage 110 and the module 200, the direction from Y1 to Y2 is also called a moving direction of the substrate S or a direction in which the substrate S is directed to the module. Since the Y axis is also a long direction of an entire substrate processing apparatus 100, the Y axis is also called a long direction of the substrate processing apparatus.

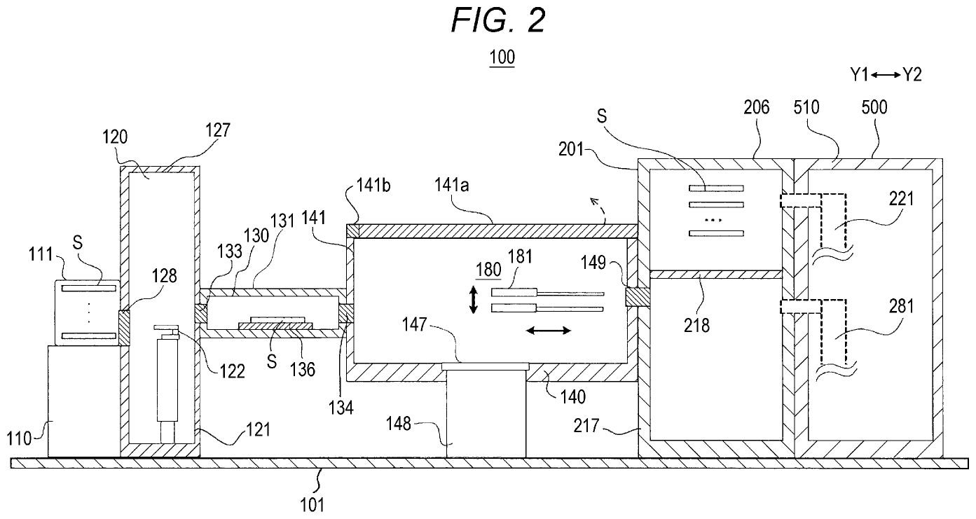

FIG. 1 is a view of the substrate processing apparatus as viewed from above, but for convenience of description, FIG. 1 also illustrates that having a different height. For example, although both a reaction tube 210 and a vacuum carry robot 180 are illustrated in the figure, the reaction tube 210 and the vacuum carry robot 180 have different heights as illustrated in FIG. 2.

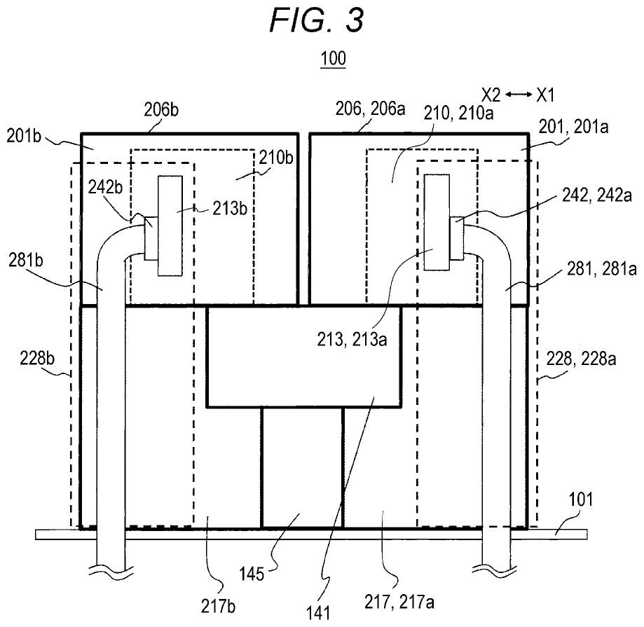

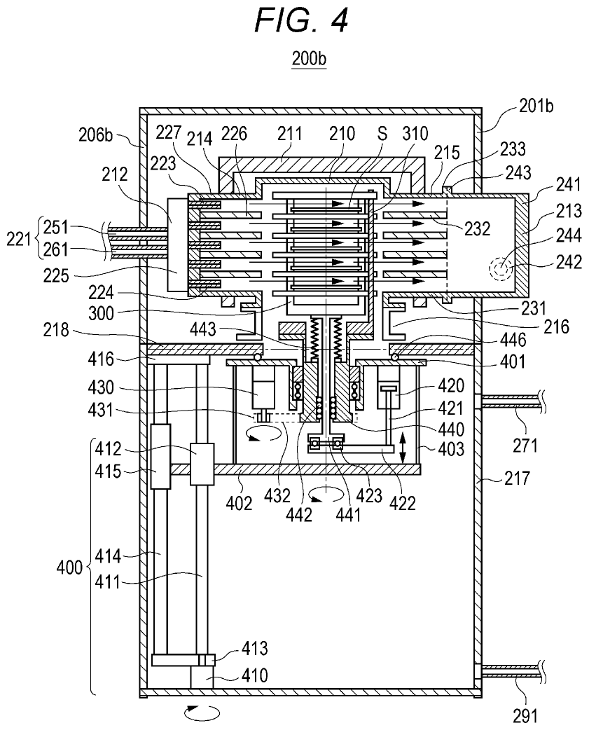

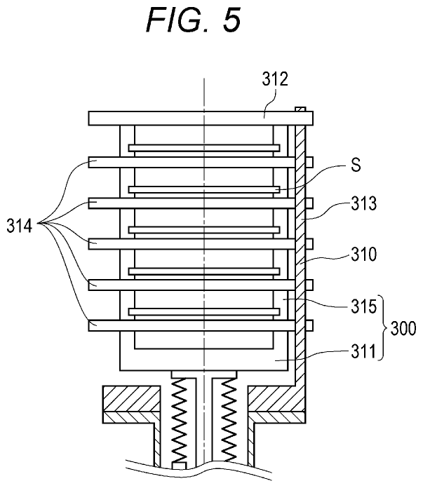

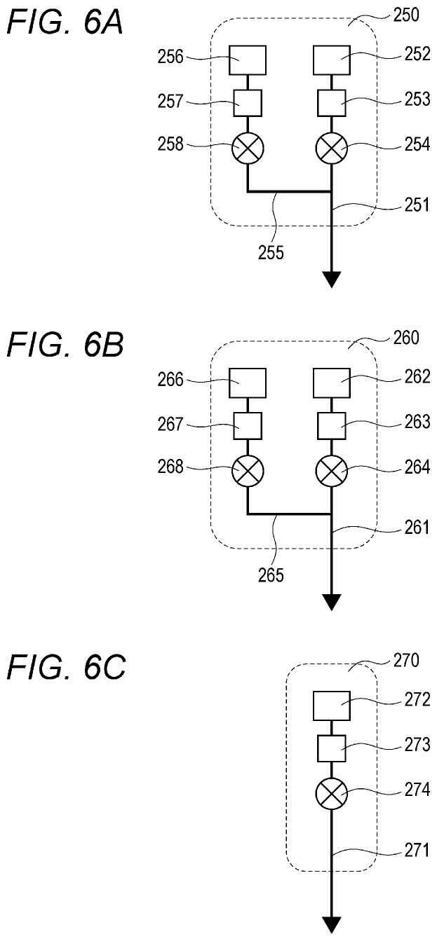

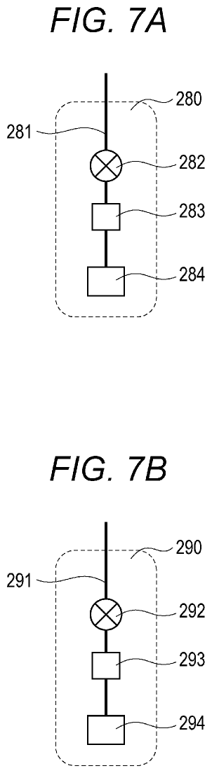

FIG. 2 illustrates a configuration example of the substrate processing apparatus according to the present aspect, and is a longitudinal cross-sectional view taken along line A-A′ in FIG. 1. FIG. 3 is an external view viewed from a line of sight C in FIG. 1. FIG. 4 illustrates a configuration example of a substrate processor according to the present aspect, and is a longitudinal cross-sectional view taken along line B-B′ in FIG. 1. FIG. 5 is an explanatory view that explains the configuration of a substrate support according to the present aspect and its periphery. FIGS. 6A to 6C are explanatory views that explain a gas supply system of the substrate processing apparatus according to the present aspect. FIGS. 7A and 7B are explanatory views that explain a gas exhaust system of the substrate processing apparatus according to the present aspect.

The substrate processing apparatus 100 processes the substrate S, and mainly includes the IO stage 110, an atmospheric carry chamber 120, a load lock chamber 130, a vacuum carry chamber 140, the module 200, and a utility box 500. Next, each configuration will be specifically described.

In FIG. 2, description of a specific structure of the module 200 is omitted for convenience of description. In FIGS. 1, 2, and 4, description of a specific structure of the utility box 500 is omitted for convenience of description.

### Atmospheric Carry Chamber and IO Stage

The IO stage (load port) 110 is installed on the front side of the substrate processing apparatus 100. A plurality of pods 111 are equipped on the IO stage 110. The pods 111 are used as a carrier for carrying the substrate S such as a silicon (Si) substrate.

The IO stage 110 is adjacent to the atmospheric carry chamber 120. In the atmospheric carry chamber 120, the load lock chamber 130 is coupled to a surface different from the IO stage 110. An atmospheric carry robot 122 for transferring the substrate S is installed in the atmospheric carry chamber 120.

A substrate loading/unloading port 128 for loading/unloading the substrate S into/from the atmospheric carry chamber 120 is installed on the front side of a housing 121 of the atmospheric carry chamber 120. The substrate loading/unloading port 128 is opened and closed by a pod opener not illustrated. A substrate loading/unloading port 133 for loading/unloading the substrate S into/from the load lock chamber 130 is provided on the back side of a housing 127 of the atmospheric carry chamber 120. The substrate loading/unloading port 133 is opened and closed by a gate valve not illustrated to enable to load and unload the substrate S.

### Load Lock Chamber

The load lock chamber 130 is adjacent to the atmospheric carry chamber 120. The vacuum carry chamber 140 described later is disposed on a surface different from the atmospheric carry chamber 120 among surfaces of a housing 131 constituting the load lock chamber 130. In the present aspect, two housings 131a and 131b are provided. The vacuum carry chamber 140 is connected via a gate valve 134. A substrate mounting table 136 on which the substrate S is mounted is installed in the load lock chamber 130.

### Vacuum Carry Chamber

The substrate processing apparatus 100 includes the vacuum carry chamber (transfer module) 140 as a carry chamber serving as a carry space in which the substrate S is carried under negative pressure. A housing 141 constituting the vacuum carry chamber 140 is formed in a pentagonal shape that is bilaterally symmetrical in plan view, and the load lock chamber 130 and the module 200 (200a and 200b) that processes the substrate S are coupled to the outer periphery.

The housing 141 includes a wall 142 adjacent to the load lock chamber 130, a wall 144 adjacent to the module 200a, a wall 145 adjacent to the module 200b, a wall 143 provided between the wall 142 and the wall 144, and a wall 146 provided between the wall 142 and the wall 145. Furthermore, a lid 141a is provided above. The lid 141a is fixed about a hinge 141b provided on the wall 142 side, and when the inside of the housing 141 or the vacuum carry robot 180 is maintained, the module 200 side of the lid 141a is raised, and the lid 141a is opened in the direction of the arrow illustrated in FIG. 2.

The wall 144 and the wall 145 are adjacent to each other so as to form a predetermined angle (for example, an obtuse angle). Therefore, the surfaces of the wall 144 and the wall 145 adjacent to the module 200 are configured radially when viewed from the center of the vacuum carry chamber 140. In the housing 141, a part including the wall 144 and the wall 145 is called a protrusion.

In a substantially center of the vacuum carry chamber 140, the vacuum carry robot 180 serving as a carrier that transfers the substrate S under negative pressure is installed with a flange 147 serving as a base. The vacuum carry robot 180 installed in the vacuum carry chamber 140 is configured to be liftable while maintaining airtightness of the vacuum carry chamber 140 by an elevator 148 and the flange 147. An arm 181 of the vacuum carry robot 180 is configured to be liftable by the elevator 148.

The vacuum carry robot 180 includes two arms 181. The arm 181 includes an end effector 182 on which the substrate S is mounted. By rotating and extending the arm 181, the substrate S is carried into the module 200, or the substrate S is unloaded from the module 200.

The modules 200 (modules 200a and 200b) are connected to the wall 144 and the wall 145, respectively. Specifically, a transfer chamber 217 of the module 200 described later is connected.

### Module

The two modules 200 are disposed in the X axis direction. The module 200a is disposed on the X1 side, and the module 200b is disposed on the X2 side. Hereinafter, in the description of the module 200, a number having “a” will describe the configuration of the module 200a, and a number having “b” will describe the configuration of the module 200b. Those not numbered are common descriptions of the modules 200.

As illustrated in FIGS. 2 and 3, a housing 201 constituting the module 200 includes a reaction tube storage chamber 206 on the upper side and the transfer chamber 217 on the lower side. A partition wall 218 is provided between the reaction tube storage chamber 206 and the transfer chamber 217. The reaction tube storage chamber 206 mainly stores the reaction tube 210. At least the transfer chamber 217 has a pentagonal shape when viewed from above. Furthermore, it is desirable that the reaction tube storage chamber 206 also has a pentagonal shape. In the present aspect, description will be made with an example in which the transfer chamber 217 and the reaction tube storage chamber 206 have the same pentagonal shape, and the entire housing 201 is configured to have a pentagonal shape when viewed from above.

Among the walls constituting the pentagonal housing, oblique walls 202 (202a and 202b) are disposed obliquely with respect to the X axis and the Y axis. The two walls extending in the X axis direction are disposed in parallel, and the two walls extending in the Y axis direction are also disposed in parallel. In the walls arranged in parallel with the X axis, the wall on the Y1 side is configured to be shorter than the wall arranged on the Y2 side. This wall on the Y1 side is called walls 203 (203a and 203b), and the wall on the Y2 side is called walls 205 (205a and 205b). In the walls disposed in parallel with the Y axis, the wall on the center side of the X axis is configured to be shorter than the wall on the outside. This wall on the center side is called walls 204 (204a and 204b). The wall 202 is disposed between the wall 203 and the wall 204.

The housing 201a and the housing 201b are configured to be bilaterally symmetrical. That is, the wall 204a and the wall 204b are configured to be adjacent to each other, and the wall 203a and the wall 203b are arranged to be adjacent to each other with the housing 141 interposed therebetween. Furthermore, the wall 202a and the wall 202b form a predetermined angle (for example, an obtuse angle, and formed by the wall 144 and the wall 145), and are adjacent to each other between the wall 202a and the wall 202b such that a space is formed on the Y1 side. The space is also called a concave portion formed by the two modules 200. The protrusion of the housing 141 is fitted into the concave portion.

Such a structure can shorten the distance from the wall 142 to the wall 205 as compared with the case of arranging quadrangular housings as described in the prior art documents. Therefore, it is possible to reduce the footprint of the substrate processing apparatus 100.

At least the transfer chamber 217 has the above-described wall. Each oblique wall 202 of the transfer chamber 217 is provided with a loading/unloading port 149 (149a and 149b) for loading/unloading the substrate S. The loading/unloading port 149 is opened and closed by a gate valve not illustrated.

A comparative example in which the shape of the transfer chamber is a quadrangular shape when viewed from above as in the related art will be considered. Here, when the lengths in the X axis direction and the Y axis direction of the pentagonal shape of the present aspect are equal to those of the comparative example, it is obvious that the area of the pentagonal shape of the present aspect is small.

Therefore, when the height of the transfer chamber of the present aspect is the same as that of the comparative example, it is obvious that the volume of the transfer chamber of the present aspect is smaller than that of the comparative example. As described later, in the present aspect, the atmosphere in the transfer chamber 217 is exhausted to bring a vacuum state, and it is possible to exhaust the atmosphere in a shorter time than that in the conventional quadrangular shape.

The reaction tube storage chamber 206 is provided with the reaction tube 210, an upstream side gas guide 214, and a downstream side gas guide 215. Specifically, a reaction tube storage chamber 206a of the module 200a is provided with a reaction tube 210a, an upstream side gas guide 214a, and a downstream side gas guide 215a. A reaction tube storage chamber 206b of the module 200b is provided with a reaction tube 210b, an upstream side gas guide 214b, and a downstream side gas guide 215b.

As described later, the upstream side gas guide 214 and the downstream side gas guide 215 are provided at positions opposing each other with the reaction tube 210 interposed therebetween. An exhaust structure 213 is connected to the downstream side of the downstream side gas guide 215. The upstream side gas guide 214, the reaction tube 210, the downstream side gas guide 215, and the exhaust structure 213 are linearly disposed.

In the reaction tube storage chamber 206a, the upstream side gas guide 214a, the downstream side gas guide 215a, the reaction tube 210a, and a part of an exhaust structure 213a are disposed. In the reaction tube storage chamber 206b, the upstream side gas guide 214b, the downstream side gas guide 215b, the reaction tube 210b, and a part of an exhaust structure 213b are disposed.

The exhaust structure 213 is configured to penetrate the wall 203 of the housing 201. Specifically, in the exhaust structure 213, the downstream side gas guide 215 side is disposed in the housing 201, and the tip on a side different from the downstream side gas guide 215 protrudes outward from the wall 203.

As described later, an exhaust pipe 281 is connected to a housing 241 constituting the exhaust structure 213. The exhaust pipe 281 is disposed in an exhaust pipe arrangement region 228 that is a region adjacent to the housing 141 and the wall 203. An exhaust pipe 281a connected to the exhaust structure 213a is disposed in an exhaust pipe arrangement region 228a, and an exhaust pipe 281b connected to the exhaust structure 213b is disposed in an exhaust pipe arrangement region 228b. Each exhaust pipe 281 penetrates a floor plate 101 having a grating structure that supports the substrate processing apparatus 100 as illustrated in FIG. 3, extends to a utility area below the floor plate 101, and is connected to a pump and the like. The exhaust pipe arrangement region 228a and the exhaust pipe arrangement region 228b are also called a piping arrangement region a and a piping arrangement region b, respectively. The piping arrangement region a and the piping arrangement region b are also collectively called the piping arrangement region.

The exhaust pipe arrangement region 228 only needs to be a region where the exhaust pipe 281 can be arranged, and may be configured by a housing, and the exhaust pipe 281 may be arranged therein. In this case, the exhaust pipe arrangement region 228 is configured to be adjacent to the reaction tube storage chamber 206 in the upper part of the housing and to be adjacent to the housing 141 of the carry chamber 140 in the lower part of the housing.

Not limited to a configuration provided with a wall such as a housing, a configuration without a wall may be adopted. In this case, a part of the floor plate 101 through which the exhaust pipe 281 penetrates is secured as the exhaust pipe arrangement region 228. With such a configuration, the lower part of the housing 141 is released to the exhaust pipe arrangement region 228 side. Then, since the person in charge of maintenance can step into the exhaust pipe arrangement region 228, the person in charge of maintenance can maintain the configuration of the vacuum carry chamber 140 such as the vacuum carry robot 180 and the elevator from the exhaust pipe arrangement region 228.

In the present aspect as illustrated in FIG. 3, the exhaust pipe 281a is connected to the X1 side of the exhaust structure 213a via an exhaust pipe connector 242a. The exhaust pipe 281b is connected to the X2 side of the exhaust structure 213b. That is, they are connected on the opposite side to the housing 141. More specifically, the exhaust pipes 281a and 281b extend toward laterally from the housing 141. Such a structure can secure a space between the exhaust pipe 281 and the housing 141, and therefore it is possible to secure a space for a person in charge of maintenance to enter, and it is possible to maintain the lower part of the housing 141. Since it is possible to secure a space between the exhaust structure 213 and the housing 141, even if the lid 141a is opened, it is possible to maintain the inside of the housing 141 and the vacuum carry robot 180 from the space. Furthermore, since it is possible to provide spaces on both sides of the housing 141, it is possible to perform maintenance from both sides of the housing 141. Providing the maintenance areas on both sides is effective, for example, when the width of the housing 141 in the X axis direction is large.

The utility box 500 is disposed on the back side (Y2 side) of the module 200. The utility box 500 is provided with an electric component box, a gas box, and the like. In FIG. 1, only a gas box 510 is illustrated for convenience of description.

The gas box 510 stores a gas supply pipe 221 (a gas supply pipe 251 and a gas supply pipe 261) described later and the exhaust pipe 281. Furthermore, a supply pipe heater that heats those gas supply pipes, a gas source, and the like are stored.

Next, a relationship with the housing 141, the housing 201, the reaction tube 210, the upstream side gas guide 214, the downstream side gas guide 215, and the exhaust structure 213 will be described.

In the reaction tube storage chamber 206a, a center line including the upstream side gas guide 214a, the downstream side gas guide 215a, the reaction tube 210a, and the exhaust structure 213a is disposed obliquely with respect to the Y axis. At this time, an extension line in the long direction of the exhaust structure 213a is disposed so as not to overlap the housing 141. The center of the reaction tube 210a as viewed from above is disposed so as to overlap the oblique wall 202a in the Y axis direction. Such a structure can make the Y1 side of the oblique wall 202a a dead area.

Similarly, also in the reaction tube storage chamber 206b, a center line including the upstream side gas guide 214b, the downstream side gas guide 215b, the reaction tube 210b, and the exhaust structure 213b is disposed obliquely with respect to the Y axis. At this time, an extension line in the long direction of the exhaust structure 213b is disposed so as not to overlap the housing 141. Such a structure can make the Y1 side of the oblique wall 202b a dead area.

Here, as a comparative example, a configuration is considered in which the center line including the upstream side gas guide 214a, the downstream side gas guide 215a, the reaction tube 210a, and the exhaust structure 213a becomes parallel to the Y axis in the reaction tube storage chamber 206a. In such a configuration, there is a possibility that either or both of the upstream side gas guide 214a and the downstream side gas guide 215a protrudes from the reaction tube storage chamber 206a. In this case, since the influence of the heater 211 becomes small, there is a possibility that the temperature is lowered at the protruding part and the gas is affected such as solidification. It is conceivable to store the upstream side gas guide 214a and the downstream side gas guide 215a in the reaction tube storage chamber 206 by increasing the width (distance between the wall 203 and the wall 205) in the Y axis direction, but this also increases the width in the Y axis direction of the transfer chamber 217 related to the reaction tube storage chamber 216 and increases the cross-sectional area, thereby increasing the volume of the transfer chamber 217. On the other hand, when the center line is oblique as described above, the upstream side gas guide 214a and the downstream side gas guide 215a can be stored without increasing the width in the Y axis direction, and furthermore, the volume of the transfer chamber 217 can be made small.

The oblique wall 202a and the oblique wall 202b in the reaction tube storage chamber 206 can secure a space in which the lid 141a of the vacuum carry chamber 140 can be raised. Therefore, even when the vacuum carry chamber 140 in which the lid 141a is released in the upward direction is provided, the vacuum reaction chamber 140 can be maintained.

Next, the configuration of the module 200 will be described with reference to FIG. 4. Here, the module 200b will be described as an example. Since the module 200a is in a relationship of line symmetry with the module 200b, the description will be omitted here. FIG. 4 is a cross-sectional view taken along line B-B′ in FIG. 1.

The reaction tube storage chamber 206b of the module 200 includes the reaction tube 210 in a cylindrical shape extending in the vertical direction, a heater 211 serving as a heater (furnace body) installed on the outer periphery of the reaction tube 210, a gas supply structure 212 serving as a gas supplier, and the gas exhaust structure 213 serving as a gas exhauster. The gas supplier may include the upstream side gas guide 214. The gas exhauster may include the downstream side gas guide 215.

The gas supply structure 212 is provided upstream in the gas flow direction of the reaction tube 210, and the gas is supplied from the gas supply structure 212 to the reaction tube 210. The gas exhaust structure 213 is provided downstream in the gas flow direction of the reaction tube 210, and the gas in the reaction tube 210 is discharged from the gas exhaust structure 213.

Between the reaction tube 210 and the gas supply structure 212, the upstream side gas guide 214 that guides the flow of the gas supplied from the gas supply structure 212 is provided. Between the reaction tube 210 and the gas exhaust structure 213, the downstream side gas guide 215 that guides the flow of the gas discharged from the reaction tube 210 is provided. The lower end of the reaction tube 210 is supported by a manifold 216.

The reaction tube 210, the upstream side gas guide 214, and the downstream side gas guide 215 have a continuous structure, and are formed of a material such as quartz or SiC, for example. These include a heat permeable material that transmits heat radiated from the heater 211. The heat of the heater 211 heats the substrate S and gas.

The gas supply structure 212 includes a distributor 225 to which the gas supply pipe 251 and the gas supply pipe 261 are connected and that distributes the gas supplied from each gas supply pipe. A plurality of nozzles 223 and 224 are provided on the downstream side of the distributor 225. The gas supply pipe 251 and the gas supply pipe 261 supply different types of gases as described later. The nozzle 223 and the nozzle 224 are disposed in an up-down relationship or a side-by-side relationship. In the present aspect, the gas supply pipe 251 and the gas supply pipe 261 are also collectively called the gas supply pipe 221. Each nozzle is also called a gas discharger.

The distributor 225 is configured to be supplied from the gas supply pipe 251 to the nozzle 223 and from the gas supply pipe 261 to the nozzle 224. For example, a path through which the gas flows is configured for each combination of the gas supply pipe and the nozzle. In this way, the gases supplied from the respective gas supply pipes do not mix with each other, and thus it is possible to suppress generation of particles that can be generated by mixing of the gases in the distributor 225.

The upstream side gas guide 214 has a housing 227 and a division plate 226. A part of the division plate 226 opposing the substrate S is extended in the horizontal direction so as to be larger than at least the diameter of the substrate S. The horizontal direction mentioned here indicates a side wall direction of the housing 227. A plurality of the division plates 226 are disposed in the vertical direction. The division plate 226 is fixed to the side wall of the housing 227, and is configured to prevent gas from moving to a lower or upper adjacent region beyond the division plate 226. A gas flow described later can be reliably formed by preventing the gas from going beyond.

The division plate 226 has a continuous structure without a hole. Each division plate 226 is provided at a position corresponding to the substrate S. The nozzle 223 and the nozzle 224 are provided between the division plates 226 and between the division plate 226 and the housing 227.

The gas flow of the gas discharged from the nozzle 223 and the nozzle 224 is guided by the division plate 226 and supplied to the surface of the substrate S. Since the division plate 226 extends in the horizontal direction and has a continuous structure without a hole, the main flow of the gas is suppressed from moving in the vertical direction and is moved in the horizontal direction. Therefore, the pressure loss of the gas reaching each substrate S can be uniformed in the vertical direction.

In a state where the substrate S is supported by a substrate support tool 300, the downstream side gas guide 215 is configured such that the ceiling becomes higher than the uppermost substrate S and the bottom become lower than the lowermost substrate S of the substrate support tool 300.

The downstream side gas guide 215 has a housing 231 and a division plate 232. A part of the division plate 232 opposing the substrate S is extended in the horizontal direction so as to be larger than at least the diameter of the substrate S. The horizontal direction mentioned here indicates a side wall direction of the housing 231. Furthermore, a plurality of the division plate 232 are disposed in the vertical direction. The division plate 232 is fixed to the side wall of the housing 231, and is configured to prevent gas from moving to a lower or upper adjacent region beyond the division plate 232. A gas flow described later can be reliably formed by preventing the gas from going beyond. A flange 233 is provided on a side of the housing 231 that is in contact with the gas exhaust structure 213.

The division plate 232 has a continuous structure without a hole. Each division plate 232 is provided at a position corresponding to the substrate S and at a position corresponding to the division plate 226. It is desirable that the division plate 226 and the division plate 232 that correspond have an equal height. Furthermore, when the substrate S is processed, it is desirable to align the height of the substrate S with the heights of the division plate 226 and the division plate 232. With such a structure, the gas supplied from each nozzle forms a flow passing on the division plate 226, the substrate S, and the division plate 232 as indicated by the arrow in the drawing. At this time, the division plate 232 has a continuous structure extending in the horizontal direction and having no hole. Such a structure can uniform the pressure loss of the gas discharged from each substrate S. Therefore, the gas flow of the gas passing through each substrate S is formed in the horizontal direction toward the exhaust structure 213 while the flow in the vertical direction is suppressed.

By providing the division plate 226 and the division plate 232, it is possible to uniform the pressure loss in the vertical direction on the upstream side and the downstream side of each substrate S, respectively, and thus, it is possible to reliably form a horizontal gas flow in which the flow in the vertical direction is suppressed over the division plate 226, the substrate S, and the division plate 232.

The gas exhaust structure 213 is provided downstream of the downstream side gas guide 215. The gas exhaust structure 213 mainly includes the housing 241 and a gas exhaust pipe connector 242. A flange 243 is provided on the downstream side gas guide 215 side of the housing 241. Since the gas exhaust structure 213 is made of metal and the downstream side gas guide 215 is made of quartz, the flange 233 and the flange 243 are fixed with a screw or the like via a cushioning material such as an O-ring. It is desirable that the flange 243 is disposed outside the heater 211 so that the influence of the heater 211 on the O-ring can be suppressed.

The gas exhaust structure 213 communicates with the space of the downstream side gas guide 215. The housing 231 and the housing 241 have a continuous height structure. The ceiling of the housing 231 is configured to have an equal height to that of the ceiling of the housing 241, and the bottom of the housing 231 is configured to have an equal height to that of the bottom of the housing 241.

The gas exhaust structure 213 is a structure without a division plate. Therefore, the gas exhaust structure 213 is also called an exhaust buffer structure without an obstacle. In the gas exhaust structure 213, an exhaust hole 244 is provided on the downstream side of the gas flow. The gas exhaust pipe connector 242 is provided outside the housing 241 at a position corresponding to the exhaust hole 244. In the horizontal direction, the distance from the gas exhaust pipe connector 242 to the downstream side edge of the substrate S becomes longer than the distance from the tip of each nozzle to the upstream side edge of the substrate S.

The gas that has passed through the downstream side gas guide 215 is exhausted from the exhaust hole 244. At this time, since the gas exhaust structure does not have a configuration such as a division plate, a gas flow including the vertical direction is formed toward the gas exhaust hole.

Next, the reason the exhaust buffer structure 215 is provided on the downstream side of the downstream side gas guide 215 will be described. As described above, although the pressure loss in the vertical direction can be uniformed to some extent by the division plate 232, it is conceivable that as it gets closer to the exhaust hole 244, the partition plate is liable to be affected by an exhaust pump 284, the gas is pulled toward the exhaust hole, and the pressure loss becomes non-uniform. Then, there is a concern that the substrate S cannot be uniformly processed in the vertical direction.

Therefore, the downstream side gas guide 215 is provided to relax the gas flow in the vertical direction. Specifically, the gas moved from the division plate 232 to the exhaust buffer structure 215 is exhausted from the exhaust hole 244, and since the exhaust hole 244 is disposed at a position away from the division plate 232 by a predetermined distance, the gas flows in the horizontal direction accordingly. This predetermined distance is a distance in which a horizontal gas flow can be formed on the division plate 232, for example. Meanwhile, since the influence of the gas flow in the horizontal direction is large, the gas flow in the vertical direction is relaxed as compared with the case where the exhaust hole 244 is provided immediately after the division plate 232.

Since the influence of the force in the vertical direction is reduced on the division plate 232, the pressure loss becomes uniform, and as a result, a horizontal gas flow can be formed on the division plate 232. Therefore, the pressure loss can be made constant on the plurality of substrates S arranged in the vertical direction, and more uniform processing can be performed.

The transfer chamber 217 is installed in a lower part of the reaction tube 210 via the manifold 216. In the transfer chamber 217, the substrate S is mounted (equipped) on the substrate support (hereinafter, may be simply called a boat) 300 by the vacuum carry robot 180 via the substrate loading port 149, and the substrate S is taken out from the substrate support 300 by the vacuum carry robot 180.

The transfer chamber 217 can store therein the substrate support 300, a partition plate support 310, and an up-down direction drive mechanism 400 constituting a first driver that drives the substrate support 300 and the partition plate support 310 (collectively called a substrate holder) in the up-down direction and the rotational direction. FIG. 4 illustrates a state in which the substrate holder 300 is raised by the up-down direction drive mechanism 400 and stored in the reaction tube.

Next, details of the substrate support will be described with reference to FIGS. 4 and 5.

The substrate support includes at least the substrate support 300, and performs replacing the substrate S by the vacuum carry robot 180 via the substrate loading port 149 inside the transfer chamber 217 and performs processing of transferring the replaced substrate S to the inside of the reaction tube 210 to form a thin film on the surface of the substrate S. The substrate support may include the partition plate support 310.

In the partition plate support 310, a plurality of disk-shaped partition plates 314 are fixed at a predetermined pitch to a column 313 supported between a base 311 and a top plate 312. The substrate support 300 has a configuration in which a plurality of support rods 315 are supported by a base 301, and the plurality of substrates S are supported by the plurality of support rods 315 at predetermined intervals.

The plurality of substrates S are mounted on the substrate support 300 at predetermined intervals by the plurality of support rods 315 supported by the base 301. Between the plurality of substrates S supported by the support rod 315 is partitioned by the disk-shaped partition plates 314 fixed (supported) to the column 313 supported by the partition plate support 310 at predetermined intervals. Here, the partition plate 314 is disposed on either or both of the upper part and the lower part of the substrate S.

The predetermined interval of the plurality of substrates S mounted on the substrate support 300 is the same as the up-down interval between the partition plates 314 fixed to the partition plate support 310. The diameter of the partition plate 314 is formed larger than the diameter of the substrate S.

The boat 300 supports a plurality of substrates S, for example, five substrates S in multiple stages in the vertical direction by a plurality of the support rods 315. The base 301 and the plurality of support rods 315 are formed of a material such as quartz or SiC, for example. Here, an example in which five substrates S are supported by the boat 300 is illustrated, but the present disclosure is not limited to this. For example, the boat 300 may be configured to be able to support about 5 to 50 substrates S. The partition plate 314 of the partition plate support 310 is also called a separator.

The partition plate support 310 and the substrate support 300 are driven by the up-down direction drive mechanism 400 in the up-down direction between the reaction tube 210 and the transfer chamber 217 and in the rotational direction around the center of the substrate S supported by the substrate support 300.

The up-down direction drive mechanism 400 constituting the first driver includes, as drive sources, an up-down driving motor 410, a rotational driving motor 430, and a boat up-down mechanism 420 including a linear actuator serving as a substrate support lifting mechanism that drives the substrate support 300 in the up-down direction.

By rotationally driving a ball screw 411, the up-down driving motor 410 serving as a partition plate support lifting mechanism moves, up and down along the ball screw 411, a nut 412 screwed into the ball screw 411. Due to this, the partition plate support 310 and the substrate support 300 are driven in the up-down direction between the reaction tube 210 and the transfer chamber 217 together with a base plate 402 to which the nut 412 is fixed. The base plate 402 is also fixed to a ball guide 415 engaged with a guide shaft 414, and is configured to be smoothly movable in the up-down direction along the guide shaft 414. The upper end and the lower end of the ball screw 411 and the guide shaft 414 are fixed to fixing plates 413 and 416, respectively.

The rotational driving motor 430 and the boat up-down mechanism 420 including the linear actuator constitute a second driver, and are fixed to a base flange 401 serving as a lid body supported by a side plate 403 to the base plate 402.

The rotational driving motor 430 drives a rotational transmission belt 432 engaged with a tooth 431 attached to the tip, and rotationally drives a support 440 engaged with the rotational transmission belt 432. The support 440 supports the partition plate support 310 by the base 311, and is driven by the rotational driving motor 430 via the rotational transmission belt 432 to rotate the partition plate support 310 and the boat 300.

The boat up-down mechanism 420 including the linear actuator drives a shaft 421 in the up-down direction. A plate 422 is attached to the tip of the shaft 421. The plate 422 is connected to a support 441 fixed to the base 301 of the boat 300 via a bearing 423. Since the support 441 is connected to the plate 422 via the bearing 423, the boat 300 can also rotate together with the partition plate support 310 when the partition plate support 310 is rotationally driven by the rotational driving motor 430.

On the other hand, the support 441 is supported by the support 440 via a linear guide bearing 442. With such a configuration, when the shaft 421 is driven in the up-down direction by the boat up-down mechanism 420 including the linear actuator, the support 441 fixed to the boat 300 can be relatively driven in the up-down direction with respect to the support 440 fixed to the partition plate support 310.

The support 440 fixed to the partition plate support 310 and the support 441 fixed to the boat 300 are connected by a vacuum bellows 443.

A vacuum sealing O-ring 446 is installed on the upper surface of the base flange 401 serving as the lid body, and as illustrated in FIG. 3, the inside of the reaction tube 210 can be kept airtight by being driven by the up-down driving motor 410 to raise the upper surface of the base flange 401 to a position where the upper surface is pressed against the transfer chamber 217.

Next, details of the gas supply system will be described with reference to FIGS. 6A to 6C.

As described in FIG. 6A, the gas supply pipe 251 is provided with a first gas source 252, a mass flow controller (MFC) 253, which is a flow rate controller, and a valve 254, which is an open/close valve, in this order from the upstream direction.

The first gas source 252 is a first gas (also called “first element-containing gas”) source containing a first element. The first element-containing gas is one of the source gas, that is, the processing gas. Here, the first element is, for example, silicon (Si). Specifically, it is a chlorosilane source gas containing a Si—Cl bond, such as hexachlorodisilane (Si₂Cl₆, abbreviation: HCDS) gas, monochlorosilane (SiH₃Cl, abbreviation: MCS) gas, dichlorosilane (SiH₂Cl₂, abbreviation: DCS), trichlorosilane (SiHCl₃, abbreviation: TCS) gas, tetrachlorosilane (SiCl₄, abbreviation: STC) gas, or octachlorotrisilane (Si₃Cl₈, abbreviation: OCTS) gas.

The gas supply pipe 251, the MFC 253, and the valve 254 mainly constitute a first gas supply system 250 (also called a silicon-containing gas supply system).

A gas supply pipe 255 is connected to the downstream side of the valve 254 in the supply pipe 251. The gas supply pipe 255 is provided with an inert gas source 256, an MFC 257, and a valve 258 serving as an open/close valve in order from the upstream direction. An inert gas, for example, nitrogen (N₂) gas is supplied from the inert gas source 256.

The gas supply pipe 255, the MFC 257, and the valve 258 mainly constitute a first inert gas supply system. The inert gas supplied from the inert gas source 256 acts as a purge gas for purging the gas remaining in the reaction tube 210 in the substrate processing step. The first inert gas supply system may be added to the first gas supply system 250.

As described in FIG. 6B, the gas supply pipe 261 is provided with a second gas source 262, an MFC 263, which is a flow rate controller, and a valve 264, which is an open/close valve, in this order from the upstream direction.

The second gas source 262 is a second gas (hereinafter, also called “second element-containing gas”) source containing a second element. The second element-containing gas is one of the processing gas. The second element-containing gas may be considered as a reactant gas or a modifying gas.

Here, the second element-containing gas contains the second element different from the first element. The second element is, for example, any one of oxygen (O), nitrogen (N), and carbon (C). In the present aspect, the second element-containing gas is, for example, a nitrogen-containing gas. Specifically, it is a hydrogen nitride-based gas containing an N—H bond, such as ammonia (NH₃), diazene (N₂H₂) gas, hydrazine (N₂H₄) gas, or N₃H₈ gas.

The gas supply pipe 261, the MFC 263, and the valve 264 mainly constitute a second gas supply system 260.

A gas supply pipe 265 is connected to the downstream side of the valve 264 in the supply pipe 261. The gas supply pipe 265 is provided with an inert gas source 266, an MFC 267, and a valve 268 serving as an open/close valve in order from the upstream direction. An inert gas, for example, nitrogen (N₂) gas is supplied from the inert gas source 266.

The gas supply pipe 265, the MFC 267, and the valve 268 mainly constitute a second inert gas supply system. The inert gas supplied from the inert gas source 266 acts as a purge gas for purging the gas remaining in the reaction tube 210 in the substrate processing step. The second inert gas supply system may be added to the second gas supply system 260.

As described in FIG. 6C, the gas supply pipe 271 is connected to the transfer chamber 217. The gas supply pipe 271 is provided with a third gas source 272, an MFC 273, which is a flow rate controller, and a valve 274, which is an open/close valve, in this order from the upstream direction. The gas supply pipe 271 is connected to the transfer chamber 217. When the transfer chamber 217 is brought into an inert gas atmosphere or the transfer chamber 217 is brought into a vacuum state, the inert gas is supplied.

The third gas source 272 is an inert gas source. The gas supply pipe 271, the MFC 273, and the valve 274 mainly constitute a third gas supply system 270. The third gas supply system is also called a transfer chamber supply system.

Next, the exhaust system will be described with reference to FIGS. 7A and 7B.

An exhaust system 280 that exhausts the atmosphere of the reaction tube 210 has an exhaust pipe 281 communicating with the reaction tube 210, and is connected to the housing 241 via an exhaust pipe connector 242.

As described in FIG. 7A, a vacuum pump 284 serving as a vacuum exhaust is connected to the exhaust pipe 281 via a valve 282 serving as an open/close valve and an auto pressure controller (APC) valve 283 serving as a pressure regulator, and is configured to be able to perform vacuum exhaust so that the pressure in the reaction tube 210 becomes a predetermined pressure (vacuum degree). The exhaust system 280 is also called a processing chamber exhaust system.

An exhaust system 290 that exhausts the atmosphere of the transfer chamber 217 has an exhaust pipe 291 connected to the transfer chamber 217 and communicating with the inside thereof.

A vacuum pump 294 serving as a vacuum exhaust is connected to the exhaust pipe 291 via a valve 292 serving as an open/close valve and an APC valve 293, and is configured to be able to perform vacuum exhaust so that the pressure in the transfer chamber 217 becomes a predetermined pressure (vacuum degree). The exhaust system 290 is also called a transfer chamber exhaust system.

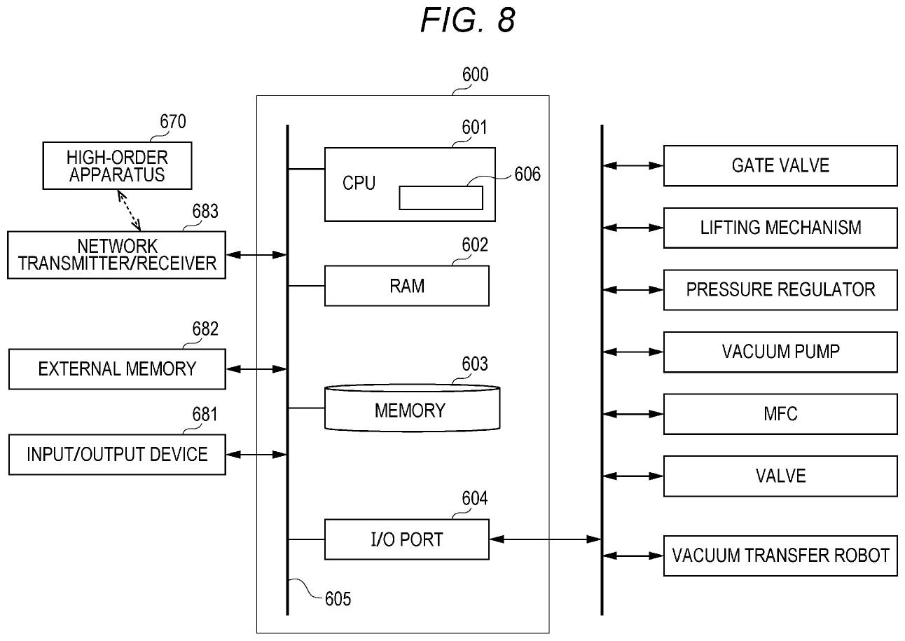

Next, the controller will be described with reference to FIG. 8. The substrate processing apparatus 100 includes a controller 600 that controls operation of each section of the substrate processing apparatus 100.

An outline of the controller 600 is illustrated in FIGS. 6A to 6C. The controller 600 serving as a controller is configured as a computer including a central processing unit (CPU) 601, a random access memory (RAM) 602, a memory 603 serving as a memory, and an I/O port 604. The RAM 602, the memory 603, and the I/O port 604 are configured to be able to exchange data with the CPU 601 via an internal bus 605. Transmission/reception of data in the substrate processing apparatus 100 is performed by support of a transmission/reception instruction section 606, which is also one function of the CPU 601.

The controller 600 is provided with a network transmitter/receiver 683 connected to a high-order apparatus 670 via a network. The network transmitter/receiver 683 can receive information regarding the processing history and the processing schedule of the substrate S stored in the pod 111 from the high-order apparatus.

The memory 603 includes, for example, a flash memory and a hard disk drive (HDD). The memory 603 readably stores therein a control program for controlling the operation of the substrate processing apparatus, a process recipe describing procedures and conditions of substrate processing, and the like.

The process recipe is a combination of procedures in a substrate processing step described later so that the controller 600 can execute the procedures to obtain a predetermined result, and functions as a program. Hereinafter, this process recipe, the control program, and the like are also collectively and simply called a program. In the present specification, the term “program” may include only a process recipe alone, only a control program alone, or both of these. The RAM 602 is configured as a memory area (work area) in which programs, data, and the like read by the CPU 601 are temporarily stored.

The I/O port 604 is connected to each configuration of the substrate processing apparatus 100.

The CPU 601 is configured to read and execute the control program from the memory 603, and to read the process recipe from the memory 603 in response to an input of an operation command from an input/output device 681 or the like. Then, the CPU 601 is configured to be able to control the substrate processing apparatus 100 in accordance with the content of the read process recipe.

The CPU 601 includes the transmission/reception instruction section 606. The controller 600 can configure the controller 600 according to the present aspect by, for example, installing a program in a computer using an external memory (for example, a magnetic disk such as a hard disk, an optical disk such as a DVD, a magneto-optical disk such as an MO, or a semiconductor memory such as a USB memory) 682 storing the above-described program. The means for supplying the program to the computer is not limited to the case of supplying the program via the external memory 682. For example, using a communication means such as the Internet or a dedicated line, the program may be supplied not via the external memory 682. The memory 603 and the external memory 682 are configured as non-transitory computer-readable recording media. Hereinafter, these are also collectively referred to simply as a recording medium. In the present specification, the term “recording medium” may include only the memory 603 alone, only the external memory 682 alone, or both of these.

Next, as one step of the semiconductor manufacturing step, a step of forming a thin film on the substrate S using the module 200 having the above-described configuration will be described. In the following description, the operation of each section constituting the substrate processing apparatus is controlled by the controller 600.

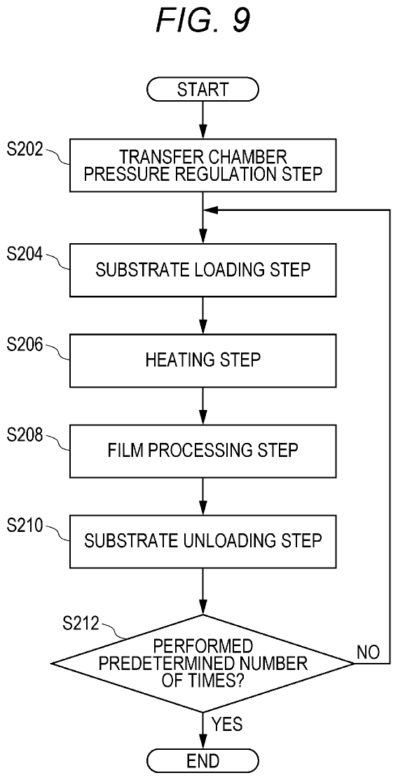

Here, film forming processing for forming a film on the substrate S by alternately supplying the first gas and the second gas will be described with reference to FIG. 9.

(S202)

A transfer chamber pressure regulation step S202 will be described. Here, the pressure in the transfer chamber 217 is assumed to be the same level as that on the vacuum carry chamber 140. Specifically, the exhaust system 290 is operated to exhaust the atmosphere in the transfer chamber 217 so that the atmosphere in the transfer chamber 217 becomes a vacuum level. As described earlier, since the volume of the transfer chamber 217 becomes smaller than that in the related art, the time for exhausting the atmosphere is shortened.

(S204)

Next, a loading step S204 will be described.

When the transfer chamber 217 reaches the vacuum level, the carrying of the substrate S is started. When the substrate S arrives at the vacuum carry chamber 140, the gate valve not illustrated adjacent to the substrate loading port 149 is released, and the vacuum carry robot 180 loads the substrate S into the transfer chamber 217.

At this time, the substrate support 300 is on standby in the transfer chamber 217, and the substrate S is transferred to the substrate support 300. When a predetermined number of substrates S are transferred to the substrate support 300, the vacuum carry robot 180 is retracted to the housing 141, and the substrate support 300 is raised to move the substrates S into the reaction vessel 210.

In the movement to the reaction vessel 210, the surface of the substrate S is positioned so as to be aligned with the height of the division plate 226 and the division plate 232.

(S206)

A heating step 5206 will be described. When the substrate S is loaded into the reaction tube 210, the inside of the reaction tube 210 is controlled to have a predetermined pressure, and the surface temperature of the substrate S is controlled to have a predetermined temperature. The temperature is, for example, room temperature or more and 700° C. or less, and preferably room temperature or more and 550° C. or less. It is conceivable that the pressure is, for example, 50 Pa to 5000 Pa.

(S208)

A film processing step S208 will be described. After the heating step S206, the film processing step S208 is performed. In the film processing step S208, according to the process recipe, the first gas supply system is controlled to supply the first gas to the reaction tube 210, and the exhaust system is controlled to exhaust the processing space, thereby performing the film processing. Here, the second gas supply system may be controlled to cause the second gas to exist in the processing space at the same time as the first gas to perform the CVD processing, or the first gas and the second gas may be alternately supplied to perform the alternate supply processing. When the second gas is processed as a plasma state, the second gas may be processed into the plasma state using a plasma generator not illustrated.

The following method is conceivable as the alternate supply processing, which is a specific example of the film processing method. For example, the first gas is supplied to the reaction tube 210 in a first step, the second gas is supplied to the reaction tube 210 in a second step, an inert gas is supplied between the first step and the second step as a purge step and the atmosphere in the reaction tube 210 is exhausted, and an alternate supply processing in which a combination of the first step, the purge step, and the second step is performed a plurality of times is performed to form a Si-containing film.

A gas flow of the supplied gas is formed in the upstream side gas guide 214, the space on the substrate S, and the downstream side gas guide 215. At this time, since the gas is supplied to the substrates S in a state where there is no pressure loss on the substrates S, uniform processing can be performed between the substrates S.

(S210)

A substrate unloading step S210 will be described. In S210, the processed substrate S is unloaded out of the transfer chamber 217 in a reverse procedure to the substrate loading step S204 described above.

(S212)

A determination S212 will be described. Here, it is determined whether the substrate has been processed a predetermined number of times. When it is determined that the processing has not been performed the predetermined number of times, the process returns to the loading step S204, and the next substrate S is processed. When it is determined that the processing has been performed the predetermined number of times, the processing is ended.

In the above description, the main flow of the gas is expressed as horizontal in the formation of the gas flow, but the main flow of the gas is only required to be formed in the horizontal direction as a whole, and the gas flow may be diffused in the perpendicular direction as long as it does not affect the uniform processing of the plurality of substrates.

In the above description, there are expressions of the same level, equivalent, equal, and the like, but it goes without saying that these include substantially the same.

### Other Aspects

Although the present aspect has been specifically described above, the present disclosure is not limited to this, and various modifications can be made without departing from the gist thereof.

For example, in the above-described aspect, a case where a film is formed on the substrate S using the first gas and the second gas in the film forming processing performed by the substrate processing apparatus has been described as an example, but the present aspect is not limited to this. That is, another type of thin film may be formed using another type of gas as the processing gas used for the film forming processing. Furthermore, even in a case where three or more types of processing gases are used, the present aspect can be applied as long as these are alternately supplied to perform the film forming processing. Specifically, the first element may be various elements, for example, titanium (Ti), silicon (Si), zirconium (Zr), and hafnium (Hf). The second element may be, for example, nitrogen (N), oxygen (O), and the like.

For example, in the above-described aspect, the film forming processing has been described as an example of the processing performed by the substrate processing apparatus, but the present aspect is not limited to this. That is, the present aspect can be applied to film forming processing other than the thin film exemplified in the embodiments in addition to the film forming processing exemplified in the embodiments. The specific content of the substrate processing may be any content, and the present disclosure can be applied not only to the film forming processing but also to other substrate processing such as annealing processing, diffusing processing, oxidizing processing, nitriding processing, and lithography processing. Furthermore, the present aspect can also be applied to other substrate processing apparatuses, for example, such as an annealing processing apparatus, an etching apparatus, an oxidation processing apparatus, a nitriding processing apparatus, an exposure apparatus, a coating apparatus, a drying apparatus, a heating apparatus, and a processing apparatus using plasma. In the present aspect, these apparatuses may be mixed. A part of a configuration of some embodiments can be replaced with a configuration of other embodiments, and a configuration of some embodiments can be added to a configuration of other embodiments. To a part of a configuration of each of the embodiments, another configuration can be added, a part of a configuration of each of the embodiments can be deleted, or a part of a configuration of each of the embodiments can be replaced with another configuration.

For example, in the above-described aspect, the exhauster is disposed on the Y1 side and the supplier is disposed on the Y2 side, but in the present aspect, for example, the supplier may be disposed on the Y1 side and the exhauster may be disposed on the Y2 side. In this case, for example, in FIG. 1, each configuration is replaced as follows.

The exhaust pipe arrangement region 228 serving as a piping arrangement region is replaced with a supply pipe arrangement region in which a supply pipe can be arranged. At this time, the supply pipe arrangement region is also called a piping arrangement region. Furthermore, the gas exhauster is disposed at a position oblique with respect to the axis of the substrate processing apparatus in the long direction (Y direction) and not overlapping the housing 141.

The present aspect has a configuration replaced as follows in FIG. 1. Specifically, the exhaust structure 213 is replaced with the supply structure 212, the downstream side gas guide 215 is replaced with the upstream side gas guide 214, and the exhaust pipe 281 is replaced with the supply pipe 221. At this time, the supply pipes 221 (supply pipes 221a and 221b) extend toward laterally from the vacuum carry chamber 140.

Furthermore, the upstream side gas guide 214 in FIG. 1 is replaced with the downstream side gas guide 215, the supply structure 212 is replaced with the exhaust structure 213, and the supply pipe 221 is replaced with the exhaust pipe 281.

As described above, the supplier may be provided on the Y1 side, and the exhauster may be provided on the Y2 side, and in these structures, the same effects as those of the above aspects can be achieved.

According to one aspect of the present disclosure, it is possible to provide a technique that can reduce the footprint.

What is claimed is:

1. A substrate processing apparatus comprising:
a module including a gas supplier having an upstream side gas guide and a supply structure, a reaction tube communicating with the gas supplier, and a gas exhauster provided at a position opposing the upstream side gas guide and having a downstream side gas guide and an exhaust structure;
a supply pipe connected to the gas supplier, and an exhaust pipe connected to the gas exhauster;
a carry chamber adjacent to a plurality of the modules; and
a piping arrangement region on a lateral of the carry chamber and adjacent to the module, the piping arrangement region in which the supply pipe or the exhaust pipe can be arranged, wherein:
the reaction tube is disposed at a position overlapping the carry chamber on a shaft of the substrate processing apparatus in a long direction;
when the supply pipe is disposed in the piping arrangement region, the gas exhauster is disposed at a position oblique to the shaft and not overlapping the carry chamber; and
when the exhaust pipe is disposed in the piping arrangement area, the gas supplier is disposed at a position oblique to the shaft and not overlapping the carry chamber.

2. The substrate processing apparatus according to claim 1 comprising:
a transfer chamber disposed below the reaction tube, wherein the carry chamber is a vacuum carry chamber; and
a transfer chamber exhaust system that brings an atmosphere of the transfer chamber into a vacuum state is connected to the transfer chamber, and the transfer chamber is configured to communicate with the vacuum carry chamber.

3. The substrate processing apparatus according to claim 1, wherein the downstream side gas guide is configured to be adjacent to the reaction tube, and the exhaust structure is configured to be disposed downstream of the downstream side gas guide.

4. The substrate processing apparatus according to claim 3, wherein the downstream side gas guide is formed of a heat permeable material, and the exhaust structure is formed of metal.

5. The substrate processing apparatus according to claim 3, wherein the gas supplier includes a distributor to which a gas supply pipe is connected on an upstream side, and the distributor and the exhaust structure are provided to oppose each other.

6. The substrate processing apparatus according to claim 3, wherein a ceiling of the downstream side gas guide is configured to become higher than the substrate disposed uppermost in a boat supporting a plurality of substrates, a bottom is configured to be lower than the substrate disposed lowermost in the boat, a ceiling of the exhaust structure has a structure continuous with the ceiling of the downstream side gas guide, and a bottom of the exhaust structure has a structure continuous with the bottom of the downstream side gas guide.

7. The substrate processing apparatus according to claim 6, wherein the downstream side gas guide has a plurality of division plates arranged in a vertical direction, and the exhaust structure is configured as an exhaust buffer structure having no obstacle from a ceiling to the bottom.

8. The substrate processing apparatus according to claim 3, wherein the downstream side gas guide has a plurality of division plates, and the division plate is configured to extend in a horizontal direction in a direction opposing the substrate.

9. The substrate processing apparatus according to claim 1, wherein:
the gas supplier includes a gas discharger; and
a distance from an edge of a substrate to a connection position of the exhaust pipe is configured to become longer than a distance from a tip of the gas discharger to the edge of the substrate.

10. The substrate processing apparatus according to claim 3, wherein the exhaust pipe is provided laterally to the exhaust structure.

11. The substrate processing apparatus according to claim 1, wherein:
when the supply pipe is disposed in the piping arrangement region, each of the supply pipes extends toward laterally from the carry chamber; and
when the exhaust pipe is disposed in the piping arrangement region, each of the exhaust pipes extends toward laterally from the carry chamber.

12. The substrate processing apparatus according to claim 1 comprising:
a reaction tube storage chamber that stores the reaction tube, wherein the piping arrangement region is constituted by a housing;
is adjacent to the reaction tube storage chamber in an upper part of the housing, and is adjacent to the carry chamber in a lower part of the housing; and
the exhaust pipe is configured to extend from the upper part to the lower part.

13. The substrate processing apparatus according to claim 1, wherein the carry chamber side is configured to be released in the piping arrangement region.

14. The substrate processing apparatus according to claim 1, wherein the piping arrangement region is configured to be adjacent via the carry chamber.

15. The substrate processing apparatus according to claim 1, wherein:
the module includes an oblique wall;
when a plurality of the modules are arranged, the oblique wall of each of the modules adjacently form a concave portion so as to form an obtuse angle; and
a protrusion of the carry chamber is configured to be fitted into the concave portion.

16. A method of processing a substrate, comprising:
loading a substrate into a reaction tube of a substrate processing apparatus including:
a module including a gas supplier having an upstream side gas guide and a supply structure, the reaction tube communicating with the gas supplier, and a gas exhauster provided at a position opposing the upstream side gas guide and having a downstream side gas guide and an exhaust structure;
a supply pipe connected to the gas supplier, and an exhaust pipe connected to the gas exhauster;
a carry chamber adjacent to a plurality of the modules; and
a piping arrangement region on a lateral of the carry chamber and adjacent to the module, the piping arrangement region in which the supply pipe or the exhaust pipe can be arranged; in which:
the reaction tube is disposed at a position overlapping the carry chamber on a shaft of the substrate processing apparatus in a long direction, when the supply pipe is disposed in the piping arrangement region, the gas exhauster is disposed at a position oblique to the shaft and not overlapping the carry chamber, and when the exhaust pipe is disposed in the piping arrangement area, the gas supplier is disposed at a position oblique to the shaft and not overlapping the carry chamber; and
processing the substrate by exhausting a gas from the reaction tube while supplying the gas from the gas supplier into the reaction tube.

17. The method of claim 16, wherein processing a substrate includes manufacturing a semiconductor device.

18. A non-transitory computer-readable recording medium storing a program, by a computer, a substrate processing apparatus to perform a process comprising:
loading a substrate into a reaction tube of a substrate processing apparatus including:
a module including a gas supplier having an upstream side gas guide and a supply structure, the reaction tube communicating with the gas supplier, and a gas exhauster provided at a position opposing the upstream side gas guide and having a downstream side gas guide and an exhaust structure;
a supply pipe connected to the gas supplier, and an exhaust pipe connected to the gas exhauster;
a carry chamber adjacent to a plurality of the modules; and
a piping arrangement region on a lateral of the carry chamber and adjacent to the module, the piping arrangement region in which the supply pipe or the exhaust pipe can be arranged; in which:
the reaction tube is disposed at a position overlapping the carry chamber on a shaft of the substrate processing apparatus in a long direction, when the supply pipe is disposed in the piping arrangement region, the gas exhauster is disposed at a position oblique to the shaft and not overlapping the carry chamber, and when the exhaust pipe is disposed in the piping arrangement area, the gas supplier is disposed at a position oblique to the shaft and not overlapping the carry chamber; and
processing the substrate by exhausting a gas from the reaction tube while supplying the gas from the gas supplier into the reaction tube.
